(19) United States
(12) Patent Application Publication
(10) Pub. No.: US 2007/0272397 A1
(43) Pub. Date: Nov. 29, 2007

(54) Compact liquid cooling unit for high end servers

(76) Inventors: Ilya Reyzin, Williamsville, NY (US); John Lawrence Pawlak, Orchard Park, NY (US); Mohinder Singh Bhatti, Amherst, NY (US)

Correspondence Address: DELPHI TECHNOLOGIES, INC., M/C 480-410-202, PO BOX 5052, TROY, MI, 48007, US

(21) Appl. No.: 11/439,043

(22) Filed: May 23, 2006

(51) Int. Cl. F28F 13/12; H05K 7/20

(52) U.S. Cl. 165/122; 361/696

(57) ABSTRACT

A closed loop liquid cooling unit for dissipating heat from an electronic device includes a housing having a bottom and a top. Opposing sides extend along a housing axis (A_{H}) between an open entrance end and an open exit end. The cooling unit further includes a cold-plate and a heat exchanger having a plurality of cooling tubes that extend between headers. A pump and a plurality of hoses circulate liquid. A heat exchanger axis (A_{HEX}) extends diagonally across the housing at an acute angle to the housing axis (A_{H}). The heat exchanger axis (A_{HEX}) defines a wedge-shaped entrance air plenum and a wedge-shaped exit air plenum. The headers are sealed for directing air through the air passages and across the cooling tubes. The pump is disposed within the wedge-shaped entrance air plenum.

### BACKGROUND OF THE INVENTION

1. Field of the Invention

The subject invention relates to a liquid cooling unit for dissipating heat generated by an electronic device, and more specifically a compact liquid cooling unit for high end servers.

2. Description of the Prior Art

Various liquid cooling units for dissipating heat generated by an electronic device are well known in the prior art. A typical liquid cooling unit includes a housing, a pump, a heat exchanger, one or more cold-plates, and a plurality of hoses. Heat exchangers typically include headers for receiving liquid and cooling tubes for delivering the liquid to each header. Traditionally, each header is disposed against a side of the housing such that the heat exchanger extends across the housing and perpendicular to the sides. A plurality of cooling fins is typically disposed between each tube for enhancing heat transfer. The hoses interconnect the pump, the heat exchanger, and the cold-plate such that the pump continuously circulates the liquid through the cooling unit.

As the liquid flows through the cold-plate, heat generated by the electronic device is transferred by the cold-plate such that the liquid is heated. Air can be moved through the housing and across the heat exchanger. The heated liquid is pumped through the heat exchanger where it is cooled by the air. The heat is transferred to the air and is exited from the housing.

High end servers utilize various electronic devices that generate heat. Traditional cooling units as described above are used to dissipate the heat from one or more electronic devices. However, extending the heat exchanger across the housing and perpendicular to the sides increases the size of the cooling unit rendering traditional heat exchangers impractical for compact servers. Accordingly, the overall size of the server may be limited by the packaging design of the liquid cooling unit. Therefore, what is desired is a liquid cooling unit packaged optimally to obtain maximum compactness and heat transfer, while minimizing air pressure drop within the housing.

### SUMMARY OF THE INVENTION AND ADVANTAGES

The invention provides for a closed loop liquid cooling unit for dissipating heat from an electronic device. The cooling unit includes a housing having a bottom and a top. The bottom and the top each have four corners. Opposing sides extend between the bottom and the top along a housing axis between an open entrance end and an open exit end. The cooling unit includes a cold-plate overlaying the electronic device and for conducting heat. The cold-plate has a plate inlet and a plate outlet. The cooling unit further includes a heat exchanger having a heat exchanger axis and at least two headers. A plurality of cooling tubes extends between the headers for delivering liquid. A plurality of cooling fins extends between each cooling tube for increasing heat transfer. The cooling unit further includes a pump having a pump inlet and a pump outlet and a plurality of hoses for circulating the liquid. The invention is distinguished by the heat exchanger axis extending diagonally across the housing and at an acute angle to the housing axis. The heat exchanger axis defines a wedge-shaped entrance air plenum adjacent the open entrance end of the housing and a wedge-shaped exit air plenum adjacent the open exit end of the housing. The headers are sealed against the opposing sides for directing air across the cooling tubes.

By extending the heat exchanger diagonally across the housing, a compact cooling unit is achieved.

### BRIEF DESCRIPTION OF THE DRAWINGS

Other advantages of the present invention will be readily appreciated, as the same becomes better understood by reference to the following detailed description when considered in connection with the accompanying drawings wherein:

FIG. 1 is a perspective view of a compact liquid cooling unit having a heat exchanger extending diagonally across the housing according to the present invention;

FIG. 2 is a top view of the compact liquid cooling unit illustrated in FIG. 1 without the housing top;

FIG. 3 is a top view of the compact liquid cooling unit illustrated in FIG. 2 with cooling fins spaced non-uniformly apart;

FIG. 4 is a top view of the compact liquid cooling unit illustrated in FIG. 2 with cooling fins positioned parallel with the housing axis;

FIG. 5 is a top view of the compact liquid cooling unit illustrated in FIG. 2 with cooling tubes bowed between an inlet header and an outlet header with cooling fins positioned perpendicular with the housing axis;

FIG. 6 is a top view of the compact liquid cooling unit illustrated in FIG. 2 with a compensator;

FIG. 7 is a perspective view of an alternative embodiment of a compact liquid cooling unit with a heat exchanger extending diagonally upwards from the housing bottom to the housing top and with headers disposed along the top and bottom of the housing, respectively; and

FIG. 8 is perspective view of an alternative embodiment of a compact liquid cooling unit with a heat exchanger extending diagonally upwards from the housing bottom to the housing top as shown in FIG. 7, but along the sides of the housing.

### DETAILED DESCRIPTION OF THE INVENTION

Referring to the Figures, wherein like numerals indicate corresponding parts throughout the several views, a liquid cooling unit 20 is generally shown for dissipating heat generated by an electronic device (not shown).

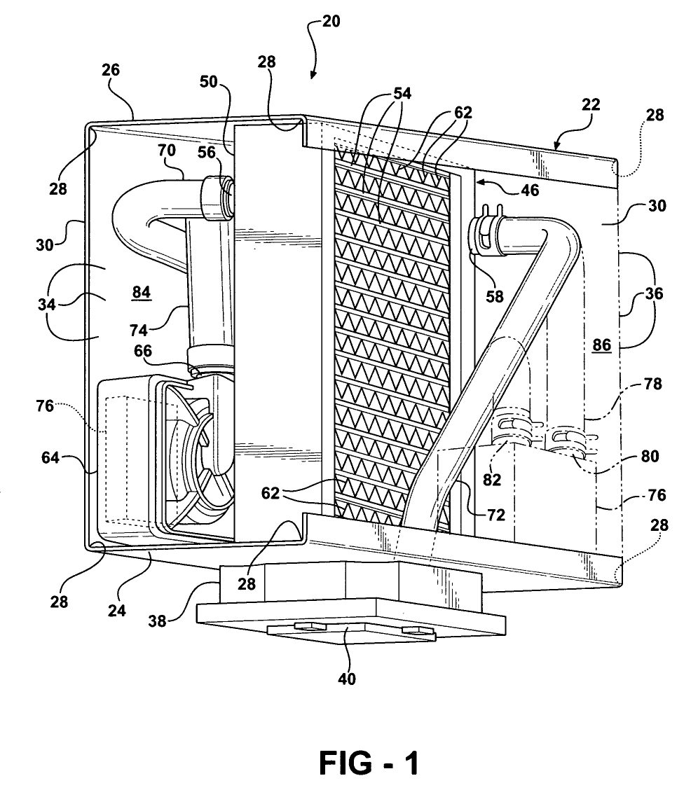

The cooling unit 20 comprises a housing 22 generally indicated having a box-like periphery. The housing 22 has a bottom 24 and a top 26 with each having four corners 28. Opposing sides 30 extend between the bottom 24 and the top 26 along a housing 22 axis (A_{H}) between an open entrance end 34 and an open exit end 36. The housing 22 defines an access opening centered at the bottom 24. Although FIGS. 1-8 show the access opening centered at the bottom 24, the opening may be located elsewhere.

The cooling unit 20 further includes a mounting frame 38 and a cold-plate 40. The mounting frame 38 defines a cold-plate 40 opening and is mounted to the bottom 24 about the access opening. The cold-plate 40 is mounted to the frame and overlays the cold-plate 40 opening. The cold-plate 40 normally overlies the electronic device for conducting heat. The cold-plate 40 has a plate inlet 42 and a plate outlet 44 for providing a path such that liquid can flow through the cold-plate 40. As liquid flows through the cold-plate 40, heat generated by the electronic device is transferred to the liquid.

A heat exchanger 46 generally indicated is used to extract heat from the liquid, as discussed further below. The heat exchanger 46 includes a heat exchanger 46 axis (A_{HEX}), an inlet header 50, an outlet header 52, and a plurality of cooling tubes 54. The inlet header 50 and the outlet header 52 have an inlet spout 56 and an outlet spout 58, respectively, for delivering liquid to and from the headers 50, 52. A plurality of cooling tubes 54 are spaced from each other and extend between the headers 50, 52. An air moving device 60 (not shown) is normally used to increase airflow through the heat exchanger 46.

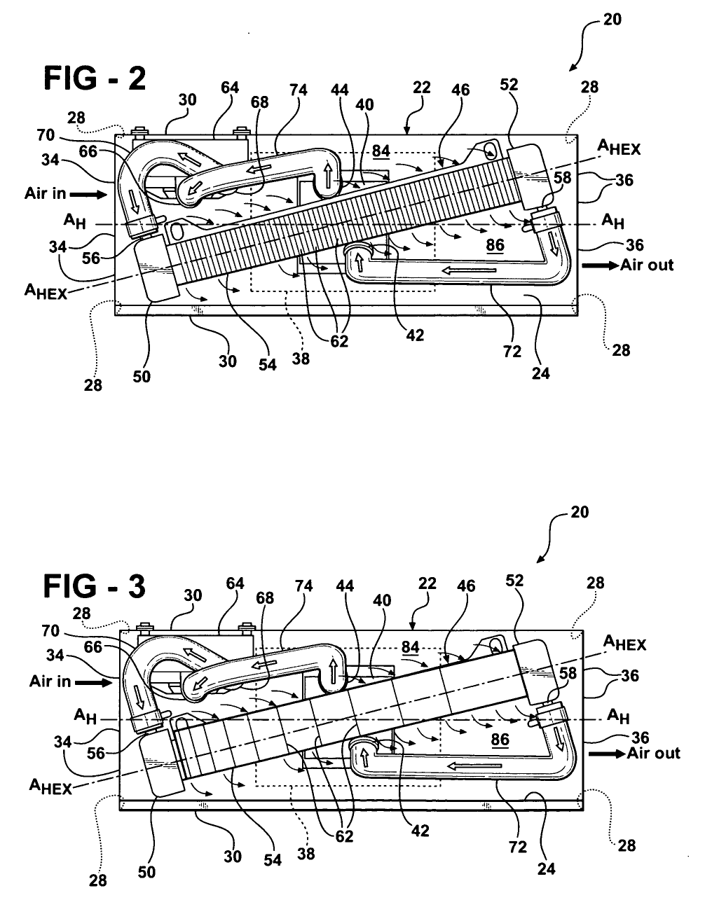

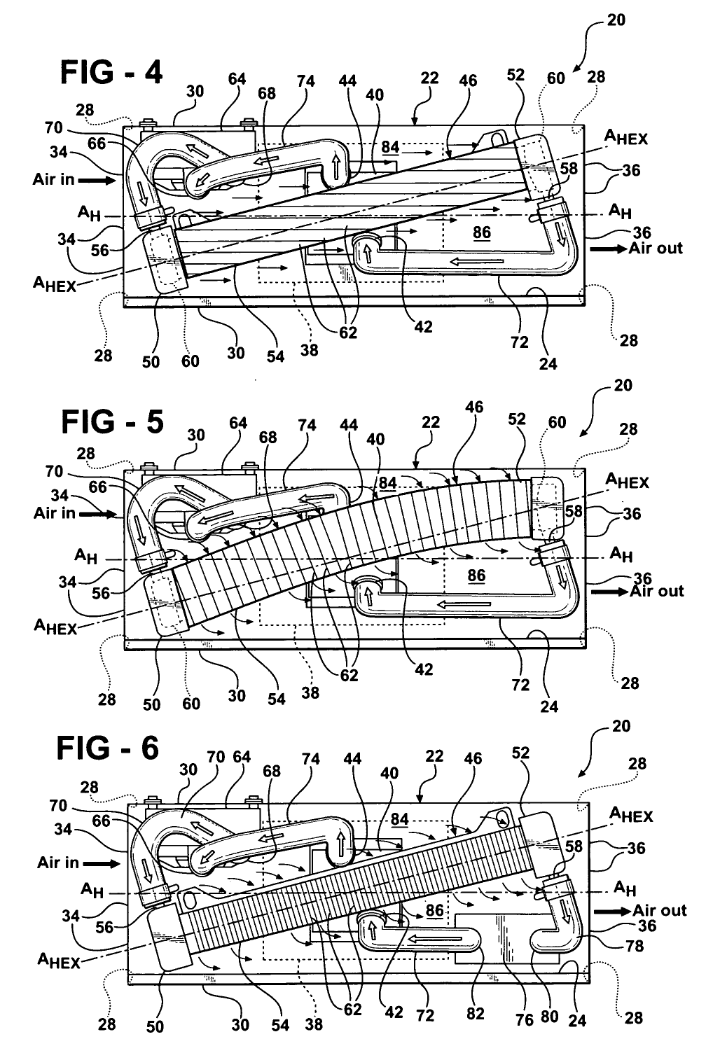

A plurality of cooling fins 62 is disposed between adjacent cooling tubes 54 to define air passages 67. Traditionally, cooling fins 62 have been disposed perpendicular to the heat exchanger 46 axis (A_{HEX}) as illustrated in FIG. 2. However, the cooling fins 62 can be disposed in various positions to optimize airflow through the air passages 67. For example, FIG. 3 shows the cooling fins 62 disposed perpendicular to the heat exchanger 46 axis (A_{HEX}) and spaced from each other at a non-uniform distance. The distance increases as the cooling fins 62 traverse from the inlet header 50 to the outlet header 52, i.e., in the direction of air flow from or along the air flow path. The non-uniform spacing increases the heat transfer surface in areas where more air pressure is available such that overall heat transfer is increased. Preferably, the cooling fins 62 are orientated parallel with the heat exchanger 46 axis (A_{HEX}) as illustrated in FIG. 4. By orientating the cooling fins 62 parallel with the heat exchanger 46 axis (A_{HEX}) the cooling fins 62 are aligned with air flowing through the housing 22 and non-productive air pressure drop can be reduced. Additionally, the longer fins increase overall surface area such that heat transfer may be increased. Alternatively, the cooling tubes 54 can be bowed between the headers 50, 52 as illustrated in FIG. 5. By bowing the heat exchanger 46, air flow uniformity can be increased. The surface area of heat exchanger 46 is also increased for increasing heat transfer. The cooling fins 62 can be disposed in positions including, but not limited to, those described above.

A pump 64 having a pump inlet 66 and a pump outlet 68 is used for pumping liquid. A pump hose 70 interconnects the pump outlet 68 to the inlet spout 56 for delivering liquid from the pump 64 to the inlet header 50. A cooling hose 72 interconnects the outlet spout 58 and the plate inlet 42 for delivering liquid from the outlet header 52 to the cold-plate 40. A return hose 74 interconnects the plate outlet 44 and the pump inlet 66 for delivering liquid to the pump 64.

A compensator 76 can be disposed within the pump 64 for maintaining liquid volume and pressure in the hoses 70, 72, 74, 78 as illustrated in FIGS. 1-5 and FIGS. 7-8. Alternatively, the compensator 76 can be disposed externally from pump 64 as illustrated in FIG. 1 and FIG. 6. The compensator 76 includes a compensator inlet 80 and a compensator outlet 82. Accordingly, a compensator hose 78 interconnects the outlet spout 58 and the compensator inlet 80 for delivering liquid from the outlet header 52 to the compensator 76. The cooling hose 72 interconnects the compensator outlet 82 to the plate inlet 42 for delivering liquid from the compensator 76 to the cold-plate 40. Although hoses 70, 72, 74, 78 are illustrated in the Figures, other conduits may be used.

The liquid cooling unit 20 is distinguished by the heat exchanger 46 axis (A_{HEX}) extending diagonally across the housing 22 and at an acute angle to the housing 22 axis (A_{H}) The heat exchanger 46 axis (A_{HEX}) defines a wedge-shaped entrance air plenum 84 adjacent the open entrance end 34 of the housing 22 and a wedge-shaped exit air plenum 86 adjacent the open exit end 36 of the housing 22. The headers 50, 52 are sealed to the housing 22 for directing air through the air passages 67 and across the cooling tubes 54. Additionally, the pump 64 is disposed on the bottom 24 in the wedge-shaped entrance air plenum 84.

FIGS. 1-5 illustrate a first embodiment having the inlet header 50 disposed vertically between the top 26 and the bottom 24 at one of the corners 28 adjacent one side at the open entrance end 34. The outlet header 52 is disposed vertically between the top 26 and the bottom 24 at another of the corners 28 adjacent the opposite side at the open exit end 36. Accordingly, the heat exchanger 46 extends diagonally across the bottom 24 of the housing 22 and the return hose 74 and the pump hose 70 define one half loop of a closed circuit. The cooling hose 72 defines one other half of the closed circuit with the half loops forming oppositely facing C shapes as viewed from above. When the compensator 76 is disposed externally from the pump 64 as illustrated in FIG. 6, the return hose and the pump hose 70 define one half loop of a closed circuit. The cooling hose 72 and the compensator hose 78 define one other half of the closed circuit with the half loops forming oppositely facing C shapes as viewed from the top 26.

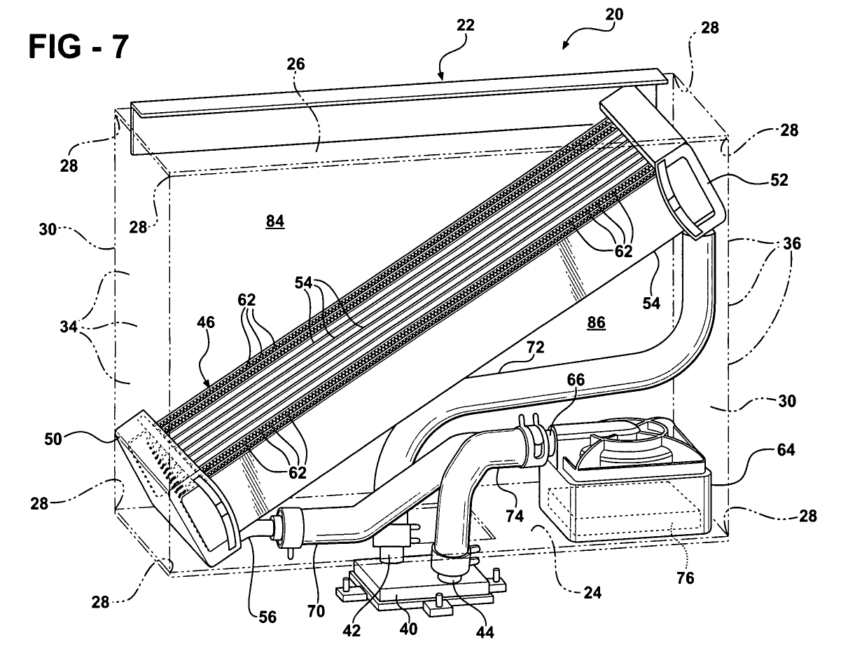

In a second embodiment illustrated in FIG. 7, the inlet header 50 is disposed at the bottom 24 adjacent to the open entrance end 34. The outlet header 52 is disposed at the top 26 adjacent the open exit end 36. The cooling tubes 54 extend between the headers 50, 52 and parallel to the heat exchanger 46 axis (A_{HEX}). Accordingly, the heat exchanger 46 extends diagonally upward from the bottom 24 adjacent to the open entrance end 34 to the top 26 adjacent to the open exit end 36.

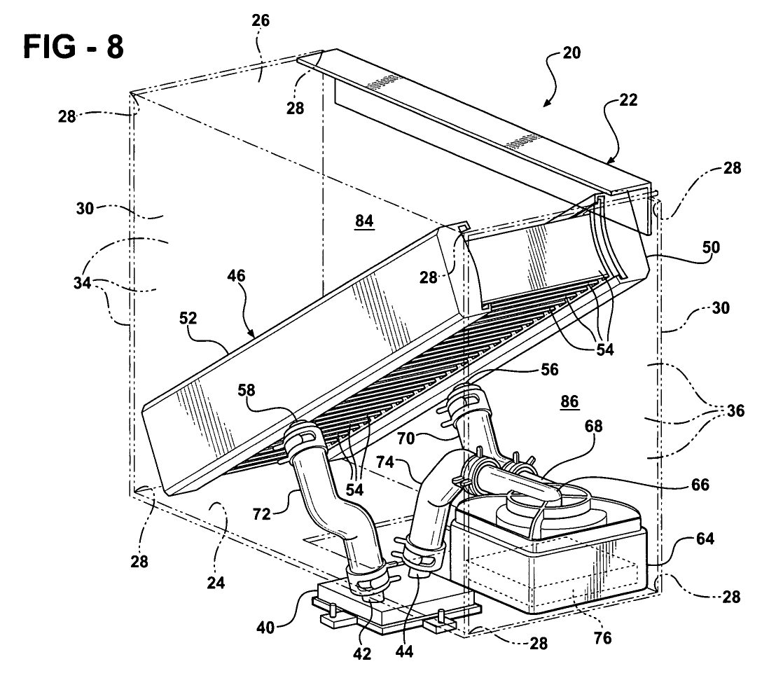

In a third embodiment illustrated in FIG. 8, the inlet header 50 is disposed horizontally between the top 26 and the bottom 24 at one of the corners 28 adjacent one side. The outlet header 52 is disposed opposite from the inlet header 50 horizontally between the top 26 and the bottom 24 at another of the corners 28. The headers 50, 52 extend from the bottom 24 adjacent the open entrance end 34 to the top 26 adjacent the open exit end 36 and parallel with the opposite sides. The cooling tubes 54 extend between the headers 50, 52 and perpendicular to the heat exchanger 46 axis (A_{HEX}). Accordingly, the heat exchanger 46 extends diagonally upward across the housing 22 from the bottom 24 to the top 26.

The cooling unit 20 is highly responsive to the instantaneous thermal load imposed on the cold-plate 40 generated by the electronic device. More specifically, the thermal load increases as liquid is heated by the electronic device through the cold-plate 40. The heated liquid is directed to the heat exchanger 46. As the heated liquid flows within the cooling tubes 54, air flows across the diagonally disposed heat exchanger 46 and through the air passage 67. The airflow removes the heat from the liquid and the heated air is exited from the housing 22. The cooled liquid is returned to the pump 64 for re-circulation.

Obviously, many modifications and variations of the present invention are possible in light of the above teachings. The invention may be practiced otherwise than as specifically described within the scope of the appended claims.

What is claimed is:

1. A closed loop liquid cooling unit for dissipating heat from an electronic device comprising;
a housing having a bottom and a top each having four corners and opposing sides therebetween extending along a housing axis (A_{H}) between an open entrance end and an open exit end,
a cold-plate for overlaying the electronic device and having a plate inlet and plate outlet,
a heat exchanger having a heat exchanger axis (A_{HEX}) and at least two headers with a plurality of cooling tubes extending between said headers,
a pump having a pump inlet and a pump outlet for pumping liquid,
a plurality of hoses for delivering the liquid,
said heat exchanger axis (A_{HEX}) extending diagonally across said housing at an acute angle to said housing axis (A_{H}) for defining a wedge-shaped entrance air plenum adjacent said open entrance end of said housing and a wedge-shaped exit air plenum adjacent said open exit end of said housing with said headers sealed for directing air through said air passages and across said cooling tubes.

2. A unit as set forth in claim 1 wherein said pump is disposed on said bottom in said wedge-shaped entrance air plenum.

3. A unit as set forth in claim 2 wherein said heat exchanger includes an inlet header and an outlet header with said inlet header having an inlet spout and said outlet header having an outlet spout and a plurality of cooling tubes spaced apart from each other extending between said headers and a plurality of cooling fins spaced at a distance from each other with said cooling fins disposed between adjacent cooling tubes to define air passages.

4. A unit as set forth in claim 3 wherein one of said plurality of hoses is a pump hose interconnecting said pump outlet and said inlet spout for delivering liquid from said pump to said inlet header.

5. A unit as set forth in claim 4 wherein one of said plurality of hoses is a return hose interconnecting said plate outlet and said pump inlet for delivering liquid to said pump.

6. A unit as set forth in claim 5 wherein one of said plurality of hoses is a cooling hose interconnecting said outlet spout and said plate inlet for delivering liquid from said outlet header to said cold-plate.

7. A unit as set forth in claim 6 wherein said inlet header is disposed vertically between said top and said bottom at one of said corners adjacent one side at said open entrance end and said outlet header is disposed vertically between said top and said bottom at the corners adjacent the other side at said open exit end whereby said heat exchanger extends diagonally across said bottom of said housing and said return hose and said pump hose define one half loop of a closed circuit and said cooling hose defines one other half of the closed circuit with said half loops forming oppositely facing C shapes as viewed from said top.

8. A unit as set forth in claim 6 wherein said inlet header is disposed horizontally between said top and said bottom adjacent one of said opposing sides and said outlet header is disposed opposite from said inlet header horizontally between said top and said bottom whereby said cooling tubes extend between said headers perpendicular to said heat exchanger axis (A_{HEX}) and said heat exchanger extends diagonally upward across from said bottom adjacent said open entrance end to said top adjacent to said open exit end.

9. A unit as set forth in claim 6 wherein said inlet header is disposed at said bottom adjacent to said open entrance end and said outlet header is disposed at said top adjacent said open exit end whereby said cooling tubes extend between said headers parallel to said heat exchanger axis (A_{HEX}) and said heat exchanger extends diagonally upward from said bottom adjacent to said open entrance end to said top adjacent to said open exit end.

10. A unit as set forth in claim 3 wherein said cooling fins are orientated parallel to said axis.

11. A unit as set forth in claim 3 wherein said cooling fins are orientated perpendicular to said axis.

12. A unit as set forth in claim 3 wherein said cooling fins are spaced from each other at a distance that is non-uniform and that increases as said cooling fins traverse from said inlet header to said outlet header.

13. A unit as set forth in claim 3 wherein said cooling tubes extend in an arc-like manner between said headers.

14. A unit as set forth in claim 5 further comprising a compensator for maintaining liquid volume and pressure in said plurality of hoses.

15. A unit as set forth in claim 14 wherein said compensator is disposed within said pump.

16. A unit as set forth in claim 14 wherein said compensator is disposed externally from said pump and adjacent to said exit opening with said compensator having a compensator inlet and a compensator outlet whereby said heat exchanger extends diagonally across said bottom of said housing and said return hose and said pump hose define one half loop of a closed circuit and said cooling hose and said compensator hose define one other half of the closed circuit with said half loops forming oppositely facing C shapes as viewed from said top.

17. A unit as set forth in claim 16 wherein said cooling hose interconnects said outlet header and said compensator inlet for delivering liquid from said outlet header to said compensator.

18. A unit as set forth in claim 17 further comprising a compensator hose interconnecting said compensator outlet and said pump inlet for delivering liquid from said compensator to said pump.

19. A unit as set forth in claim 1 further comprising at least one air moving device fixed to at least one of said inlet header and said outlet header for moving air parallel with said axis through said housing from said open entrance end to said open exit end.

20. A unit as set forth in claim 1 wherein said housing is box-like.

21. A unit as set forth in claim 1 wherein said cooling tubes have an elongated cross-section.

22. A unit as set forth in claim 1 wherein said bottom defines an access opening centered at said bottom.

23. A unit as set forth in claim 22 further comprising a mounting frame defining a cold-plate opening and mounted to said bottom about said access opening.

24. A unit as set forth in claim 23 wherein said cold-plate is mounted to said frame and overlays said cold-plate opening.

25. A closed loop liquid cooling unit for dissipating heat from an electronic device comprising;
a box-like housing having a bottom and a top each having four corners and opposing sides therebetween extending along a housing axis (A_{H}) between an open entrance end and an open exit end,
said bottom of said housing defining an access opening,
a mounting frame defining a cold-plate opening and mounted to said bottom about said access opening,
a cold-plate mounted to said frame and overlaying said cold-plate opening for overlaying the electronic device,
said cold-plate centered on said bottom and having a plate inlet and a plate outlet for circulating liquid through said cold-plate for conducting heat generated by the electronic device,
a heat exchanger having a heat exchanger axis (A_{HEX}) and including an inlet header and an outlet header and a plurality of cooling tubes spaced from each other and extending between said headers and a plurality of cooling fins spaced at a distance from each other, said cooling fins disposed between adjacent cooling tubes to define a plurality of air passages,
said inlet header having an inlet spout and said outlet header having an outlet spout,
a pump having a pump inlet and a pump outlet for pumping liquid,
a pump hose interconnecting said pump outlet and said inlet spout for delivering liquid from said pump to said inlet header,
a cooling hose for delivering liquid to said cold-plate,
a return hose interconnecting said plate outlet and said pump inlet for delivering liquid to said pump,
a compensator for maintaining liquid volume and pressure in said hoses,
said heat exchanger axis (A_{HEX}) extending diagonally across said housing and at an acute angle to said housing axis (A_{H}) for defining a wedge-shaped entrance air plenum adjacent said open entrance end of said housing and a wedge-shaped exit air plenum adjacent said open exit end of said housing with said headers sealed for directing air through said air passages and across said cooling tubes and said pump being disposed on said bottom in said wedge-shaped entrance air plenum.

26. A unit as set forth in claim 25 wherein said cooling tubes extend perpendicular to said heat exchanger axis (A_{HEX}).

27. A unit as set forth in claim 25 wherein said inlet header is disposed vertically between said top and said bottom at one of said corners adjacent one side at said open entrance end and said outlet header is disposed vertically between said top and said bottom at the corners adjacent the other side at said open exit end whereby said heat exchanger extends diagonally across said bottom of said housing and said return hose and said pump hose define one half loop of a closed circuit and said cooling hose defines one other half of the closed circuit with said half loops forming oppositely facing C shapes as viewed from said top.

28. A unit as set forth in claim 26 wherein said inlet header is disposed horizontally between said top and said bottom at one of said corners adjacent one side and said outlet header is disposed opposite from said inlet header horizontally between said top and said bottom at another of said corners whereby said headers extend from said bottom adjacent said open entrance end to said top adjacent said open exit end parallel with said opposite sides such that said heat exchanger extends diagonally upward across from said bottom said top adjacent to said open exit end and where said cooling tubes extend between said headers perpendicular to said heat exchanger axis (A_{HEX}).

29. A unit as set forth in claim 25 wherein said inlet header is disposed at said bottom adjacent to said open entrance end and said outlet header is disposed at said top adjacent said open exit end whereby said cooling tubes extend between said headers parallel to said heat exchanger axis (A_{HEX}) such that said heat exchanger extends diagonally upward from said bottom adjacent to said open entrance end to said top adjacent to said open exit end.

30. A unit as set forth in claim 25 wherein said cooling fins are orientated parallel to said housing axis (A_{H}).

31. A unit as set forth in claim 25 wherein said cooling fins are orientated perpendicular to said housing axis (A_{H}).

32. A unit as set forth in claim 25 wherein said cooling fins are spaced at a non-uniform distance from each such that said distance increases as said cooling fins traverse from said inlet header to said outlet header.

33. A unit as set forth in claim 25 wherein said cooling tubes extend in an arc-like manner between said headers.

34. A unit as set forth in claim 25 wherein said compensator is disposed within said pump.

35. A unit as set forth in claim 34 wherein said cooling hose interconnects said outlet header and said plate inlet.

36. A unit as set forth in claim 25 wherein said compensator is disposed externally from said pump and adjacent to said exit opening with said compensator having a compensator inlet and a compensator outlet.

37. A unit as set forth in claim 36 further comprising a compensator hose that interconnects said outlet spout and said compensator inlet for delivering liquid from said outlet header to said compensator.

38. A unit as set forth in claim 37 wherein said cooling hose interconnects said compensator outlet and said plate inlet for delivering liquid from said compensator to said cold-plate whereby said heat exchanger extends diagonally across said bottom of said housing and said return hose and said pump hose define one half loop of a closed circuit and said compensator hose and said cooling hose define one other half of the closed circuit with said half loops forming oppositely facing C shapes as viewed from said top.

39. A unit as set forth in claim 25 further comprising at least one air moving device fixed to at least one of said inlet header and said outlet header for moving air parallel with said axis through said housing from said open entrance end to said open exit end.
